(19) United States
(12) Patent Application Publication
(10) Pub. No.: US 2023/0268565 A1
(43) Pub. Date: Aug. 24, 2023

(54) IDENTIFICATION, CONFIGURATION AND CONTROL OF AN ELECTRIC APPLIANCE

(71) Applicant: EINHELL GERMANY AG, Landau/Isar (DE)

(72) Inventor: Markus THANNHUBER, Landau/Isar (DE)

(21) Appl. No.: 18/169,936

(22) Filed: Feb. 16, 2023

(30) Foreign Application Priority Data
Feb. 21, 2022 (DE) 10 2022 104 039.9

(51) Int. Cl. H01M 10/42; G01R 31/396; G06K 7/10

(52) U.S. Cl. CPC H01M 10/4257; G01R 31/396; G06K 7/1097; H01M 2220/30; H01M 2010/4278; H01M 2010/4271

(57) ABSTRACT

According to a method for controlling a first electric appliance (4) by means of a battery pack (1), which is selectively connectable to the first electric appliance (4) and at least one second electric appliance, a generic software for controlling the first electric appliance (4) and the at least one second electric appliance is stored on a storage element of the battery pack (1). Identification information, which identifies the first electric appliance (4), is obtained by the battery pack (1) and configuration information is requested and obtained from an external computer system (10) by means of the battery pack (1) depending on the identification information. The software is configured according to the configuration information and the first electric appliance (4) is controlled by means of the battery pack (1) by execution of the configured software.

### FIELD

The present invention relates to a method for controlling a first electric appliance by means of a battery pack, which is selectively connectable to the first electric appliance and to at least one second electric appliance. Furthermore, the invention is directed to a corresponding battery pack.

### BACKGROUND

The networking of physical appliances and virtual objects with each other as well as the cooperation thereof based on information and communication technologies, also known under terms like “Internet of Things”, IoT, is increasingly part of the private and public everyday life. Thereby, the appliances and systems can interact themselves with each other on the one hand, also with human users on the other hand. Examples for the application reach from home automation over the safety technology, the predictive maintenance of machines up to the life sciences.

A further example is the cloud-based control and monitoring of electric appliances such as for instance electric tools, household appliances and gardening tools. Thus, an irrigation pump can for example optimally automatically irrigate an area according to a learned irrigation behavior depending on the temperature profile, rainfalls, cloudiness and soil condition. In addition, it is possible to realize a user support depending on project, a parameterization of the electric tool depending on project, a wear estimation of wearing parts of the electric tool depending on project and so on by interaction of a cloud computer system with the electric appliance or the battery pack thereof depending on project. A coupled operation of multiple electric appliances is also possible.

In the development of electric appliances capable of IoT, the individual programming and adaptation of the electric appliance and/or of the battery pack results in increased effort. Thus, it is for example required to enable the electronics, which controls the electric tool, for example via pulse width modulation, PWM, of the power or current output from the battery pack to the electric appliance, not only principally via a firmware, to for example control an electrical load of the electric appliance, for instance a motor, but also to provide the required information how the control can and is to be effected in detail, based on which measurement values, limit values, parameters or models the control is performed and so on. Moreover, it is desirable to enable electric appliances, which are optionally natively not capable of IoT, by corresponding retrofit or the like thereto.

### SUMMARY

It is an object of the present invention to enable a generic battery pack for controlling a concrete electric appliance in simple and flexible manner.

This object is solved by the respective subject matter of the independent claims. Advantageous developments and preferred embodiments are the subject matter of the dependent claims.

The invention is based on the idea to first equip the battery pack for the electric appliance with a generic software for controlling different electric appliances, then to identify the concrete electric appliance and to request and obtain configuration information for specific configuration of the software from an external computer system by means of the battery pack based on the identification.

According to an aspect of the invention, a method for controlling a first electric appliance by means of a battery pack is provided. Therein, the battery pack can be, in particular electrically and mechanically, selectively connected to the first electric appliance and at least one second electric appliance, in particular for energy supply. A generic software for controlling the first electric appliance and the at least one second electric appliance is stored on a storage element of the battery pack. Identification information, which identifies the first electric appliance, is obtained by the battery pack, for example a processing circuit of the battery pack. Depending on the identification information, configuration information is, in particular wirelessly, requested and obtained from an external computer system by means of the battery pack, in particular via a first communication interface of the battery pack, and in particular stored, for example on the storage element of the battery pack or a further storage element of the battery pack. The generic software is for example configured by means of the processing circuit according to the obtained configuration information, in particular by means of the battery pack. The first electric appliance is controlled by means of the battery pack by executing the configured software, in particular via a second communication interface of the battery pack.

That the software is a generic software for controlling the first electric appliance as well as the at least one second electric appliance, can in particular be understood such that the software, in particular after a corresponding specific configuration, is in principle suitable both for controlling the first electric appliance and for controlling the at least one second electric appliance, in particular if the battery pack is mechanically and electrically connected to the first electric appliance or to the corresponding second electric appliance. According to which concrete electric appliance is actually to be controlled by the battery pack and the software, different configuration information may be required, or a different configuration of the initially generic software is required. In particular, it can be that the generic software is not capable of being employed for controlling the first and/or a second electric appliance before a corresponding configuration. Only after a specifically adapted software has become from the software by configuration of the generic software, such a control is then for example possible. Thus, in the method according to the invention, the software is a generic software until it has been configured according to the configuration information. The configured software is then no longer generic and is in particular suitable for controlling the first electric appliance, but not necessarily for controlling one of the second electric appliances.

The same can be analogously transferred to the battery pack itself. Thus, the battery pack is in particular a generic battery pack for controlling the first electric appliance and the at least one second electric appliance as long as the software has not been configured. Thereafter, it is a configured or specifically adapted battery pack.

In other words, the configuration information is associated, in particular individually associated, with the first electric appliance, wherein the association is in particular effected via the identification information. Thus, the storage of the generic software on the battery pack can for example be effected during the production or at the end of the production of the battery pack before the battery pack is delivered to a user. If it is then certain, with which electric appliance the battery pack is concretely used, thus, if the first electric appliance is defined, then the first electric appliance is identified by the battery pack according to the invention in that the battery pack obtains the identification information.

Then, the configuration information can be centrally retrieved from the external computer system depending on the identification information and be loaded onto the battery pack for configuration of the concrete software on the battery pack.

If the configuration of the software has been performed according to the configuration information, then the first electric appliance can be correspondingly controlled by means of the battery pack, in particular an electrical load of the electric appliance, for example a motor, can then be controlled by the battery pack in suitable manner. For controlling the first electric appliance by means of the battery pack, in particular in the operation, a communication of the electric appliance with the external computer system is in particular not required therein.

Thus, the generic software can for example be a firmware, thus a software, which is in particular functionally firmly connected to a hardware of the battery pack, such that the battery pack is not usable without the software, at least is not usable for the control of the first electric appliance or the at least one second electric appliance, and the software either is not usable without the battery pack or the hardware of the battery pack. The storage element, which can for example be configured as a programmable memory, and thereby the software are in particular a constituent of the processing circuit. For example, the storage element can be configured as a flash memory, EPROM, EEPROM or ROM or as a non-persistent storage element, for example RAM.

Here, and in the following, an electric appliance can for example be an electric tool, an electric or electronic household appliance, an electric or electronic gardening tool, an electrically driven vehicle, in particular small vehicle, for example an electric scooter or an electric bicycle, and so on.

The first electric appliance and the at least one second electric appliance in particular differ from each other. Therein, the differences between the first electric appliance and the at least one second electric appliance can be of fundamental nature, thus, they can be completely different types of electric appliances, for example a screwdriver on the one hand and a lawn mower on the other hand. However, the first and the at least one second electric appliance can also differ in less fundamental characteristics, such as for example a maximum power input, a specification of the concrete electrical load or certain executable functions. For example, both the first electric appliance and the at least one second electric appliance can be impact drills, wherein the first electric appliance is to be supplied with another operating voltage than the second electric appliance. Of course, these concrete examples are only intended for illustration and do not restrict the invention in any way.

The storage of the generic software on the storage element of the battery pack can be effected independently of whether the battery pack is electrically or mechanically connected to the first electric appliance or is in the immediate or farther environment of the first electric appliance or not. According to embodiment, the identification information can be provided to the battery pack in different manner. Accordingly, obtaining the identification information by the battery pack can also be effected in different embodiments if the battery pack is not or not yet electrically and/or mechanically connected to the first electric appliance. This correspondingly also applies to requesting and obtaining the configuration information and the configuration of the software. Before the first electric appliance is controlled by the battery pack, however, the battery pack is, in particular mechanically and electrically, connected to the first electric appliance.

The external computer system is referred to as external because it is in particular arranged externally to the electric appliance and externally to the battery pack and in particular is not mechanically or electrically connected to them. The external computer system can include one or more server computers, also referred to as cloud computers, or a physical and/or virtual compound of server computers and/or other external computing units. Alternatively or additionally, the external computer system can include one or more mobile electronic appliances, such as for instance mobile phones, smartphones, tablet computers, notebook computers and so on, and/or stationary computing units, such as for instance personal computers, PC.

Preferably, the configuration information is wirelessly requested and obtained from the external computer system by means of the battery pack. The wireless communication between the battery pack and the external computer system can for example be effected via a radio network, for instance a mobile radio network, a WLAN network or a low power wide area network, LPWAN, in particular an NB IoT (Narrowband Internet of Things) network. In particular, the radio network can be configured according to GSM, UMTS, LTE, 5G, 6G and so on or NB IoT. Further, not cell-based approaches such as for instance LoRa, ZigBee or Sigfox are also possible.

The identification information allows identifying the concrete first electric appliance or the type of the first electric appliance. Thus, an identification of exactly one single electric appliance can be possible by the identification information or only an identification of similarly constructed and/or configured electric appliances. In any case, all electric appliances, which are defined by the identification information and with which the same configuration information is correspondingly associated, can be controlled by the correspondingly configured software.

The processing circuit can obtain the identification information in different manners according to the implementation of the battery pack and/or of the electric appliance. For example, the battery pack can comprise a capturing device, for example a reader for reading visual information or electronically stored information, for example by means of RFID (radio-frequency identification) technology to obtain or capture the identification information and to transfer it to the processing circuit.

Alternatively or additionally, the processing circuit can obtain the identification information in electronic, in particular digital, form from the electric appliance via the second communication interface if a communication link between the electric appliance and the second communication interface of the battery pack is established, or via a further communication interface of the battery pack for data exchange with the first electric appliance. The communication link can be wireless in some embodiments. Alternatively or additionally, the processing circuit can also obtain the identification information via a mechanical and electrical connection of the battery pack to the first electric appliance, for example via a digital bit code, which is transferred via corresponding contacts, or via the evaluation of specific voltage and/or resistance values at such contacts.

Alternatively, a connectionless communication between the processing circuit or the further communication interface of the battery pack and the first electric appliance can also be effected, for example by means of Bluetooth or another broadcast signal.

Alternatively or additionally, the processing circuit can obtain the identification information via a mechanical encoding. For example, a grid can be encoded at a mechanical junction of the first electric tool for connection to the battery pack, for instance a corresponding shoe, which can be scanned and contains the identification information.

In summary, the processing circuit can obtain the identification information in particular via the capturing device of the battery pack, via the second communication interface or via the further communication interface of the battery pack for data exchange with the first electric appliance.

The configuration information is associated with the identification information and thereby with the first electric appliance or similar electric appliances. The association can be predetermined, it can in particular be stored on the external computer system. In particular, the configuration information contains information to the effect how certain control operations for controlling the first electric appliance can be coordinated and/or performed by the battery pack. The control operations can be relatively simple generic control operations for controlling the load of the electric appliance, such as for instance an operation of the load with a constant current input, a constant motor speed, a constant motor torque, a certain predefined torque profile, a certain predefined speed profile and so on. However, the control operations can also include more complex operations, for example by combination of multiple generic control operations in a predefined manner.

The configuration information can also include models or information about models for ageing or control or for the electromechanical or physical behavior of the electric appliance or the load, which the battery pack can use for controlling the first electric appliance. The configuration information can also include limit values for certain parameters, thus parameter ranges, for example relating to parameters to pulse width modulation or to current output or to power output or to the evaluation of other sensors, such as for instance temperature sensors, temperature ranges, temperature limit values and so on. The configuration information can also include information to the effect how the battery pack can infer state characteristics of the electric appliance, of the battery pack and/or of the load of the electric appliance from the current input or power input or voltage input of the load, for example based on so-called ripples. The configuration information can also include information on the communication of the first electric appliance with a further electric appliance, for example the at least one second electric appliance or a third electric appliance, and/or information on the communication of the battery pack with a further battery pack. In this manner, a coupled operation of multiple battery packs and/or electric appliances can for example be coordinated and performed.

It is to be pointed out that the control of the first electric appliance does not necessarily have to be effected exclusively via the battery pack. This can be the case, but it can also be that the first electric appliance has own electronics or hardware and/or software, for example firmware, for controlling certain functions or fundamental procedures.

Thus, according to the invention, a universally usable battery pack, thus in particular a battery pack selectively suitable for controlling the first electric appliance as well as the at least one second electric appliance, can be controlled largely independently of the concrete design of the first electric appliance and independently of the concrete requirements thereof with respect to the control by the battery pack. This is achieved in that the battery pack, in particular the generic software, is configured based on the corresponding configuration information only when it is defined or certain, which electric appliance the first electric appliance concretely is, thus what the identification information of the first electric appliance is.

Accordingly, the battery pack can be used for any compatible electric appliances, including the first electric appliance and the at least one second electric appliance. Besides the control of the first electric appliance, the battery pack, alone or in combination with one or more further battery packs, can also serve for energy supply of the first electric appliance, in particular of the electrical load of the first electric appliance. To this end, the battery pack in particular comprises at least one battery cell, for example at least one lithium-based battery cell. The combination of the control functionality with the energy supply of the first electric appliance in the battery pack is particularly advantageous since the at least one battery cell of the battery pack can thereby also be employed for the energy supply of the processing circuit and for the energy supply for communication of the battery pack with the external computer system without an additional energy source being required thereto.

The battery pack can be detachably, in particular non-destructively detachably, connected to a housing of the first electric appliance, for example via a locking connection, a plug connection and/or a clamping connection. In particular, the mechanical connection of the battery pack to the housing of the first electric appliance can be configured as a form-fit and/or force fit connection without a firmly bonded connection being present. In other words, the mechanical connection of the battery pack to the housing of the first electric appliance can be detached without a firmly bonded connection having to be detached. Preferably, the mechanical connection can be manually detached without the employment of other tools as intended. In other words, the battery pack is configured as an exchangeable battery pack, in particular system battery pack. For electrical and mechanical connection, the housings of the battery pack and of the first electric appliance can comprise respective interfaces, wherein the corresponding interface of the battery pack can be combined with the second communication interface.

An electrical connection of the at least one battery cell to the first electric appliance, in particular the load of the first electric appliance, for example a motor of the first electric appliance, can for example be effected via one or more detachable electrical contacts, for example clamping contacts or plug contacts, in particular so-called tulip contacts or blade contacts. For example, plugs or sockets or receptacles or the like each compatible with each other can be provided at the interfaces of the corresponding housings to achieve the electrical connection of the battery pack to the electric appliance. Therein, the detachable electrical contacts on the side of the battery pack can be a part of the second communication interface or be provided separately thereto.

The explanations with respect to the mechanical and/or electrical connection of the battery pack to the first electric appliance can be analogously transferred to the electrical and/or mechanical connection of the battery pack to the at least one second electric appliance. For example, a corresponding housing of the at least one second electric appliance can be configured identically or largely identically to the housing of the first electric appliance in this respect.

According to at least one embodiment of the method, the control of the first electric appliance by means of the battery pack includes a control of a current output by the battery pack, in particular by the at least one battery cell, to the first electric appliance, in particular to the electrical load, and/or an electrical power output by the battery pack, in particular the at least one battery cell, to the first electric appliance, in particular the load. Therein, the control of the current and/or the power can for example be effected based on a PWM control.

According to at least one embodiment, at least one electronic switching element of the battery pack, which can selectively establish and interrupt a current flow from the battery pack, in particular the at least one battery cell, to the first electric appliance, is controlled for controlling the current and/or the electrical power.

Therein, the at least one electronic switching element can in particular include at least one transistor, for example power transistor, in particular field effect transistor, for example power field effect transistor.

In addition to the control of the at least one electronic switching element, the control of the current and/or the electrical power can also include selectively connecting or coupling and switching off or decoupling one or more capacitive energy storages and/or one or more inductive energy storages to the at least one battery cell and from the at least one battery cell, respectively, in some embodiments. In this manner, the power output to the first electric appliance or the voltage provided to the first electric appliance can for example be individually limited, for example in the PWM control.

In various embodiments, the control of the first electric appliance by means of the battery pack can also include a control of one or more other actuators of the battery pack and/or of the first electric appliance.

According to at least one embodiment, a runtime environment is generated by means of the configured software and the first electric appliance is controlled by means of the battery pack by the runtime environment.

According to at least one embodiment, further configuration information is, in particular wirelessly, transferred to the battery pack, in particular the processing circuit, by means of the external computer system after the configuration of the software according to the configuration information. The configuration of the software is changed according to the further configuration information, in particular by means of the processing circuit.

In other words, the configuration of the software or firmware can thus be changed or updated, for example by means of OTA (over the air), without having to completely newly install the software or firmware.

According to at least one embodiment, the first electric appliance is positioned in a spatial capturing range of a reader, for example a reader of the battery pack or a reader provided externally to the battery pack. The identification information is captured by means of the reader, in particular when the first electric appliance is positioned in the capturing range, and in particular transferred to the processing circuit.

The reader can be a reader for reading visual or optical information, for example a barcode scanner or the like, or a reader for reading electronic or digital information in wireless or wired manner, for example by means of RFID. Accordingly, the capturing range of the reader can be more or less spatially extended. In order to bring the first electric appliance into the capturing range of the reader, the battery pack can be mechanically and/or electrically connected to the first electric appliance in some embodiments. However, this is not necessarily the case since the identification information can also be exchanged with the battery pack at another location of the first electric appliance than it is provided for connection of the battery pack to the first electric appliance, for example based on a visually readable code or an RFID transponder.

According to at least one embodiment, the identification information is obtained from an RFID transponder of the first electric appliance by means of a reader by radio-frequency identification, RFID.

In other words, the reader of the battery pack is configured as an RFID reader. The RFID reader is for example connected to the processing circuit and configured to obtain the identification information from the RFID transponder and to transfer it to the processing circuit.

In this manner, a contactless transfer of the identification information can in particular be achieved, which is for example advantageous if the second communication interface is designed wirelessly. In addition, the RFID transponder, which is also referred to as RFID tag, can be readily exchanged or be attached afterwards.

Even if the battery pack is mechanically connected to the first electric appliance, the transfer of the identification information by means of RFID can be advantageous since the RFID transponder can be flexibly arranged at any positions of the electric appliance such that the battery pack can obtain the identification information for example before attachment to the first electric appliance. RFID-based solutions are also advantageous with regard to a retrofitting capability of the IoT functionality.

According to at least one embodiment, a visually readable code of the first electric appliance is read by means of the reader and the identification information is determined based on the read visually readable code, in particular by means of the processing circuit. Thus, the reader of the battery pack is in particular formed as an optical reader, which is connected to the processing circuit and configured to read the visually readable code.

The visually readable code can for example be given as a line code, barcode, two-dimensional QR code or the like or also in the form of a character string or the like. For example, the optical reader can be configured as a barcode scanner or QR scanner or as a camera module of the battery pack.

Alternatively, the optical reader can also be provided externally to the battery pack, for example in a mobile electronic terminal such as for instance a mobile phone. Then, the optical reader can for example include a camera of the mobile phone or other mobile electronic terminal. The mobile electronic terminal is then optionally in communication link with the battery pack and/or the external computer system. For example, the electronic terminal can directly or indirectly transfer the read code to the battery pack, and the battery pack can correspondingly request the configuration information. Analogously, the RFID reader can also be provided externally to the battery pack in some embodiments, for example in the mobile electronic terminal.

According to at least one embodiment, a digital code is obtained via an electrical connection of the battery pack to the first electric appliance by means of the battery pack, in particular by means of the processing circuit via the second communication interface, and the identification information is determined based on the digital code, in particular by means of the processing circuit.

Therein, the battery pack is in particular mechanically and electrically connected to the first electric appliance before obtaining the digital code. The digital code is in particular a bit code, thus for instance a bit sequence, which can be sent from the electric appliance by means of a digital signal transfer and can be obtained by the battery pack via the second communication interface and transferred to the processing circuit.

Therein, the digital signal or the digital code can in particular be transferred in wired manner via corresponding electrical contacts of the second communication interface or in wireless manner. In this way, the hardware on the side of the battery pack required for obtaining the identification information can be simplified.

According to at least one embodiment, a voltage value and/or a resistance value on at least one electrical contact of the battery pack are determined, in particular by means of the processing circuit, for example via the second communication interface, while the battery pack is electrically connected to the first electric appliance, in particular via the at least one electrical contact. The identification information is determined based on the voltage value and/or the resistance value, in particular by means of the processing circuit.

Thus, a particularly simple determination of the identification information can be realized.

For example, the second communication interface can be configured as a universal asynchronous receiver-transmitter interface, UART interface.

Such a design is particularly advantageous due to the low complexity of UART interfaces and due to the fact that only two communication lines are required for data exchange.

In alternative embodiments, the second communication interface can also be configured as an I²C (inter-integrated circuit) interface.

According to at least one embodiment, a plurality of datasets is stored on the external computer system, wherein a first dataset of the plurality of datasets contains the configuration information and at least one second dataset of the plurality of datasets contains respective further configuration information for the at least one second electric appliance. In response to the request of the configuration information, in particular by the battery pack, the first dataset is selected from the plurality of datasets depending on the identification information and transferred to the battery pack by means of the external computer system.

In this manner, the battery pack thus obtains the configuration information depending on the identification information and in response to the request, respectively.

In the request of the configuration information, the content thereof is in particular not yet set by the battery pack. Rather the request of the configuration information can be understood such that the battery pack requests configuration information suitable for the first electric appliance based on the identification information and the external computer system then selects and transfers it as described.

In this manner, a plurality of datasets can thus be provided for different electric appliances and the battery pack or the software can be configured concretely adapted to the specific requirements of the first electric appliance. In this manner, it is in particular also possible that the configured battery pack is first used with the first electric appliance as described and with one of the at least second electric appliance at a later point of time. Hereto, the battery pack can then again request configuration information based on further identification information, which identifies the second electric appliance, and obtain it from the external computer system and correspondingly adapt the configuration of the software.

Alternatively, multiple software modules can be provided on the battery pack, which are configured corresponding to different configuration information, such that the battery pack is usable for different electric appliances, for example the first electric appliance and the second electric appliance, without having to again retrieve corresponding configuration information from the external computer system.

According to at least one embodiment, a predefined first control operation for controlling the first electric appliance is requested, the request of the first control operation is captured by means of the battery pack and the first electric appliance is controlled by means of the battery pack depending on the configuration information or by the execution of the configured software for performing the first control operation.

Therein, the request of the first control operation can be effected manually, in particular directly or indirectly, or automatically. With a manual request, a user input can for example be performed at the first electric appliance, at the battery pack or at the mobile electronic terminal. The manual request can also be indirectly effected in that a user uses the first electric appliance as intended, for example by actuation of an input element for activating the electrical load. Alternatively or additionally, the request can also be effected in automated manner, for example depending on a current project or project status.

Thus, the configuration information or a part of the configuration information in particular defines how the battery pack has to control the first electric appliance such that the first electric appliance performs or can perform the first control operation.

Therein, the first control operation can correspond to a certain operating mode of the first electric appliance, for example on certain defined conditions, such as for instance a constant speed of the motor or a constant torque of the motor or a certain speed or torque profile of the motor and so on or a constant operating current and so on. Such relatively simple operating modes or operating conditions can also be referred to as generic control operations, GCO. However, the first control operation can also be of more complex nature, in particular specify two or more GCOs or other predefined procedures or functions.

According to at least one embodiment, a second control operation for controlling the battery pack is requested, the request of the second control operation is captured by means of the battery pack and the second control operation is performed by means of the battery pack depending on the configuration information or by the execution of the configured software.

Therein, the second control operation in particular also has effects on the first electric appliance such that performing the second control operation also at least indirectly represents a control of the first electric appliance. The second control operation can for example correspond to a certain configuration or a certain mode of a PWM control of the current or power output by the battery pack.

With respect to the request of the second control operation and the characteristics of the second control operation, reference is analogously made to the explanations to the first control operation.

According to at least one embodiment, a user input is recognized, in particular by means of the battery pack, and the request of the first control operation and/or the second control operation is captured depending on the user input.

Therein, as already indicated above, the user input can be effected at the first electric appliance, at the battery pack, at a mobile electronic terminal such as for instance a smartphone, at a stationary computing device, for instance a PC, for example via a web application or a web browser application.

If the user input is not directly effected at the battery pack, corresponding sensor data or sensor signals relating to the input at the first electric appliance can for example be transferred to the battery pack or the processing circuit or corresponding information relating to the user input can be transferred from the mobile electronic terminal, the stationary computing unit or the external computer system to the battery pack, in particular in wireless manner.

The user input can be effected at the first electric appliance for example via a start lever or start button for operating the electric appliance or via a specific switch or another input element of the first electric appliance or of the battery pack. The user input can also be effected via voice input via a microphone of the electric appliance or of the battery pack or of the mobile electronic terminal and so on.

According to at least one embodiment, a current project step of a project to be performed is determined depending on the user input, in particular by means of the processing circuit or by means of the external computer system or by means of the mobile electronic terminal, and the first control operation and/or the second control operation are requested depending on the current project step.

For example, the project can comprise a sequence of project steps, wherein at least a part of the project steps can for example be performed using the first electric appliance operable with the battery pack. In various project steps, different electric appliances can also be employable. The sequence of project steps for example defines an order of the individual project steps. For example, the order of the project steps is required or advantageous to be able to perform the desired project. Therein, a project step can include one or more activities, which are to be performed by the user. User information for one or more project steps can be stored in a data storage of the battery pack, of the electric appliance and/or of the external computer system. The user information for example describes one or more activities and/or a designation of the respective project step and/or electric appliance to be employed and/or another accessory and/or material to be employed or the like. For example, the user information can include information relating to one or more requirements or recommendations for performing the respective project step, such as for instance information relating to a tool selection or tool configuration. Alternatively or additionally, the user information can also include information to sizes, measures, shape dimensions, position dimensions, material parameters and so on. The user information can also include information relating to the corresponding order of the project steps within the sequence.

For example, a current project status can be determined and the current project step can be determined depending on the current project status. Therein, the project status in particular corresponds to the information, which project steps of the sequence of project steps are already past or done and which ones are still pending and which one is the current or imminent project step, respectively. For example, the processing circuit can determine this information based on a predetermined schedule, based on a user input and/or on measurements of operating parameters of the first electric appliance or of the battery pack.

According to at least one embodiment, an operating current for operating the electrical or electronic load of the first electric appliance and/or an operating voltage for operating the load and/or a power output of an energy source of the battery pack, in particular of the at least one battery cell, to the load are monitored by means of the battery pack. The current project step of the project to be performed is determined depending on a result of monitoring and the first control operation and/or the second control operation are requested depending on the current project step.

According to at least one embodiment, status information is obtained by means of wireless communication by means of the battery pack and the current project step of the project to be performed is determined depending on the status information. The first control operation and/or the second control operation are requested depending on the current project step.

According to at least one embodiment, a predefined third control operation for controlling a third electric appliance is requested and the request of the third control operation is captured by means of the battery pack. Depending on the configuration information or by execution of the configured software, a message is transferred from the battery pack to the third electric appliance, in particular in wireless or wired manner. The third control operation is performed by means of the third electric appliance depending on the transferred message.

Therein, the request of the third control operation can for example be performed based on sensor data of one or more sensors of the first electric appliance and/or of the battery pack.

In this manner, a coupled operation of the first and the third electric appliance can be achieved. Therein, the communication or the coupling of the first and the third electric appliance is also set by the configuration information.

Therein, the transfer of the message from the battery pack to the third electric appliance can be effected directly, in particular directly and wirelessly, from the battery pack to the third electric appliance or indirectly in that the battery pack for example transfers the message to the external computer system and the external computer system transfers the message to the third electric appliance.

Therein, the third electric appliance can for example include a further battery pack for energy supply of the third electric appliance. In some embodiments, the communication of the third electric appliance with the battery pack and/or with the external computer system can then be partially or completely realized by the further battery pack of the third electric appliance. For example, an active operating mode of the third electric appliance can be activated or changed if the first one is activated.

According to at least one embodiment, the third control operation is requested depending on an activation of the first electric appliance, in particular an activation of the electrical or electronic load of the first electric appliance.

The first electric appliance or the load is thus activated, the activation is detected, in particular by one or more sensors of the first electric appliance and/or of the battery pack, and the third control operation is requested based thereon or in response thereto.

The coupling of the first and the third electric appliance can be realized in various manners. For example, the third electric appliance can be activated whenever, for example only if, the first electric appliance is also activated. On the other hand, the third electric appliance can also be deactivated if the first electric appliance is activated, or an operating mode of the third electric appliance can be changed depending on the activation of the first electric appliance in another manner.

According to a further aspect of the invention, a battery pack is provided, which is selectively, in particular electrically and/or mechanically, connectable to a first electric appliance and at least one second electric appliance, in particular for energy supply. The battery pack comprises a storage element, which stores a generic software for controlling the first electric appliance and the at least one second electric appliance. The battery pack comprises a processing circuit, which is configured to obtain identification information, which identifies the electric appliance. The battery pack comprises a communication interface, in particular a first communication interface, which is configured for wireless data exchange with an external computer system. The processing circuit is configured to wirelessly request and obtain configuration information from the external computer system via the communication interface depending on the identification information. The processing circuit is configured to configure the software according to the obtained configuration information and to control the first electric appliance by executing the configured software.

Further embodiments of the battery pack according to the invention immediately follow from the different configurations of the method according to the invention and vice versa. In particular, individual features and corresponding explanations with respect to the different embodiments to the method according to the invention can be analogously transferred to corresponding embodiments of the battery pack according to the invention. In particular, the battery pack according to the invention is formed or programmed for performing a method according to the invention. In particular, the battery pack according to the invention performs the method according to the invention.

Further features of the invention are apparent from the claims, the figures and the description of figures. The features and feature combinations mentioned above in the description as well as the features and feature combinations mentioned below in the description of figures and/or shown in the figures can be encompassed by the invention not only in the respectively specified combination, but also in other combinations. In particular, implementations and feature combinations can also be encompassed by the invention, which do not comprise all of the features of an originally formulated claim. Moreover, implementations and feature combinations can be encompassed by the invention, which extend beyond or deviate from the feature combinations set forth in the relations of the claims.

### BRIEF DESCRIPTION OF THE DRAWINGS

In the following, the invention is explained in more detail based on concrete embodiments and associated schematic drawings. In the figures, identical or functionally identical elements can be provided with the same reference characters. The description of identical or functionally identical elements is optionally not necessarily repeated with respect to various figures.

FIG. 1 is a schematic representation of an exemplary embodiment of a battery pack according to the invention.

FIG. 2 is a schematic representation of a further exemplary embodiment of a battery pack according to the invention.

FIG. 3 is a schematic representation of a further exemplary embodiment of a battery pack according to the invention.

### DETAILED DESCRIPTION

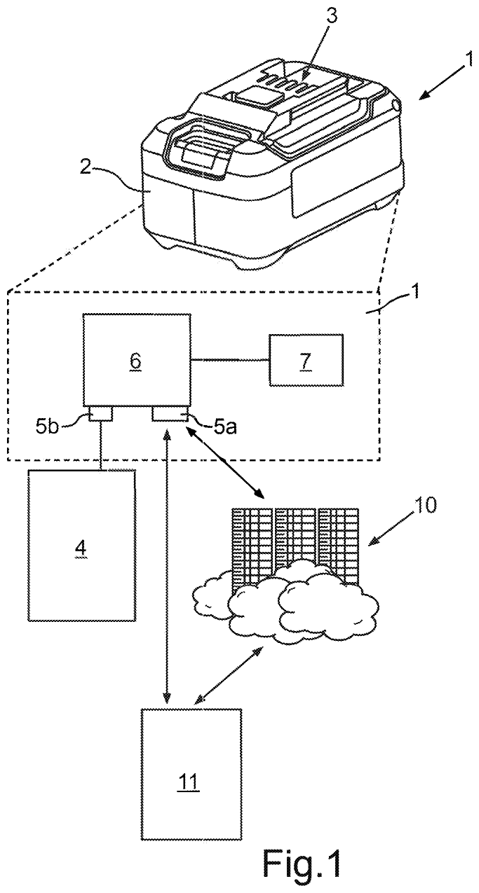

In FIG. 1, an exemplary embodiment of a battery pack 1 according to the invention is schematically illustrated, which can be electrically and mechanically connected to an electric appliance 4, for example an electric tool, for energy supply of the electric appliance 4, for example of an electric motor of the electric appliance 4. Further, an external computer system 10 is illustrated.

The battery pack 1 is a generic battery pack, also referred to as system or exchangeable battery pack, which can be connected to further electric appliances (not illustrated) for the energy supply thereof instead of the electric appliance 4. Therein, the further electric appliances are not necessarily of the same type as the electric appliance 4.

The battery pack 1 comprises a storage element (not illustrated), which stores a generic software for selective control of the electric appliance 4 and the further electric appliances, wherein a control of the electric appliance 4 or the further electric appliances in particular requires a specific configuration of the initially generic software.

The battery pack 1 in particular comprises a housing 2 and an interface 3 for mechanical and electrical connection of the housing 2 or of the battery pack 1 to a corresponding housing (not illustrated) of the electric appliance 4.

The battery pack 1 comprises a processing circuit 6 as well as a first communication interface 5a for wireless communication with the external computer system 10. In addition, the battery pack 1 comprises a second communication interface 5b for wireless or wired communication with the electric appliance 4. The interface 3 can represent a part of the second communication interface 5b or be provided in addition to the second communication interface 5b.

In addition, the battery pack 1 comprises an electrical energy storage 7, in particular one or more battery cells interconnected in series and/or parallel with each other, for energy supply of the electric appliance 4 and in particular also for energy supply of all of the electronic components of the battery pack 1 itself.

The processing circuit 6 can obtain identification information relating to the electric appliance 4, for instance in the form of a digital code, for example via the second communication interface 5b. The processing circuit 6 can then request configuration information from the external computer system 10 via the first communication interface 5a depending on the identification information and obtain it from the external computer system 10 in response thereto.

The processing circuit 6, in particular a software module (not illustrated) of the processing circuit 6, is configured to configure the initially generic software according to the configuration information. Then, the processing circuit 6 can execute the configured software, thus in particular at least a part of the configured software, and thereby control the first electric appliance 4.

In some embodiments, a user input can be captured, for example via a user interface of the external computer system 10, and the configuration information for the software relating to the control of the electric appliance 4 by the battery pack 1 can be determined depending on the user input, for example by means of the external computer system 10.

The user, for instance a developer, can correspondingly specifically set the configuration information for the electric appliance 4 without a complete programming of the software being required.

The control of the electric appliance 4 by execution of the software can in particular include one or more predefined control operations specified, configured or parameterized based on the configuration information. These control operations can represent relatively simple routines or operating modes of the electric appliance 4 and/or of the battery pack 1, which can for example be referred to as GCOs (generic control operation). Possible examples for GCOs are for instance a supply of the electric appliance 4 and by the battery pack 1 with a constant current or a constant electrical power, for example via PWM control, the operation of the electric motor of the electric appliance 4 with a constant speed or a constant torque and so on. A GCO can also realize a predefined correlation of two or more operating parameters with each other, for instance a predefined relation between motor speed and motor torque, between motor speed and output power and so on.

A GCO can also define a predetermined dynamic profile of one or more operating parameters, for example motor speed, motor torque, output power and so on, for instance within the scope of a start operation in activating the electric motor of the electric appliance 4 or the like. Such start operations can for example be defined by so-called soft start profiles such that a certain operating parameter is for example not immediately adjusted to a target value when the electric appliance 4 is activated, but a continuous course of the operating parameter, for instance of the motor speed, of the motor torque, the output power and so on, is for example achieved.

Moreover, the control operations can also implement more complex operating modes or operating profiles, for instance by combination of two or more GCOs. Thus, concrete tasks or activities, which a user wishes to perform with the electric appliance 4, can for example be performed in controlled and optimized manner, respectively. If the electric appliance 4 is for example configured as a screwdriver and if a certain type of screw is to be screwed in therewith, thus, a corresponding control operation can for example combine a soft start profile followed by an operation with constant speed over a certain period of time and/or number of revolutions. Thereafter, the speed can for example be reduced and a predetermined torque can be set. However, this is only a non-restricting example.

In order to be able to control such and further control operations, the software requires detailed information, parameter values, parameter limits and so on for the individual control operations, adapted to the concrete electric appliance 4. This information can be individually and flexibly provided in the form of the configuration information.

In some embodiments, the battery pack 1, in particular the processing circuit 6, can communicate with a further electric appliance 11 or a further battery pack (not illustrated) of the further electric appliance 11, for example via the first communication interface 5a or a further communication interface (not illustrated). This communication can be effected directly or indirectly via the external computer system 10.

In this manner, a coupled operation of the electric appliance 4 with the further electric appliance 11 can for example be implemented. The coupling can be effected in very different manners. For example, the electric appliance 11, for instance an extraction system or a lamp, can be activated exactly when the electric appliance 4, for instance a saw, is activated. Alternatively, the electric appliance 11, for example a lawn mower, can be deactivated when the electric appliance 4, for instance an irrigation system, is activated. Various further possibilities are conceivable according to configuration of the electric appliance 4 and the further electric appliance 11.

For communication of the electric appliance 4 with the further electric appliance 11, a corresponding configuration of the battery pack 1 or of the software can also be required. This too can be realized based on the configuration information. Then, the control operations can correspondingly also relate to or specify the communication of the electric appliance 4 with the further electric appliance 11.

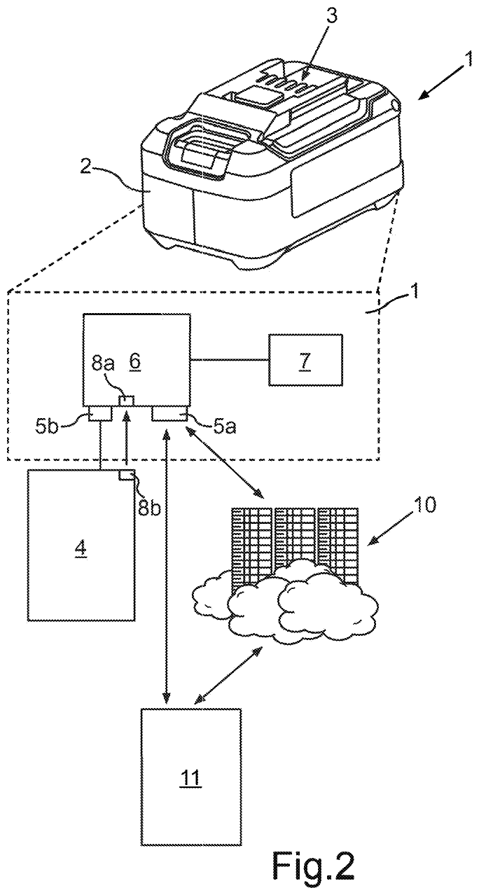

In FIG. 2, a further exemplary embodiment of the battery pack 1 is schematically illustrated. The battery pack 1 is based on the battery pack 1 described with reference to FIG. 1, wherein the identification information is here read out of an RFID transponder 8b of the electric appliance 4 by an RFID reader 8a of the battery pack 1.

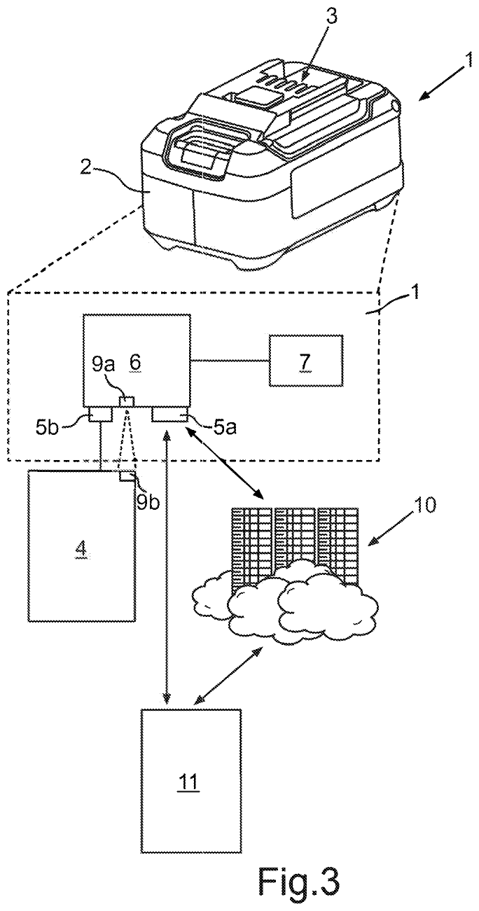

In FIG. 3, a further exemplary embodiment of the battery pack 1 is schematically illustrated, which is based on the embodiment of FIG. 1.

Here, the battery pack 1 comprises an optical reader 9a, for example a barcode scanner, which can read a corresponding visually readable code 9b of the electric appliance 4 and transfer the read code to the processing circuit 6 to provide the identification information, which is contained in the read code.

As was in particular explained based on the figures, the invention allows a universal and flexible employment of a battery pack, which is basically suitable for different electric appliances, and a specific control of an individual electric appliance by the battery pack corresponding to the concrete possibilities, requirements and characteristics of the individual electric appliance at the same time.

In preferred embodiments, the battery pack communicates with the electric appliance via a UART interface or an FC interface and wirelessly obtains the configuration information from a cloud.

For example, a generic firmware for controlling various electric appliances can initially be stored on the battery pack. For example, a set of parameters can be captured based on a user query via a cloud application and corresponding configuration information can be transferred to the battery pack. It can then correspondingly configure or parameterize the firmware such that the battery pack can initiate and control defined GCOs or more complex control operations.

Then, the firmware can accept measurement values or other signals or information from sensors of the battery pack or of the individual electric appliance, for instance current sensors, voltage sensors, temperature sensors and so on, optionally process them and/or use or provide them for performing control operations. Further, the firmware can optionally control actuators of the battery pack, for instance power transistors for PWM control of the output current and the like. The firmware can possibly also accept required command sets and suitably pass or implement them.

The individual GCOs or more complex control operations can be requested manually by a user input and/or controlled by cloud and/or in automatic manner for example depending on project and be performed.

### LIST OF REFERENCE CHARACTERS

1 Battery pack
2 housing
3 interface
4 electric appliance
5a communication interface
5b communication interface
6 processing circuit
7 energy storage
8a RFID reader
8b RFID transponder
9a optical reader
9b visually readable code
10 external computer system
11 electric appliance

1. A method for controlling a first electric appliance by means of a battery pack, which is selectively connectable to the first electric appliance and at least one second electric appliance, wherein
a generic software for controlling the first electric appliance and the at least one second electric appliance is stored on a storage element of the battery pack;
identification information, which identifies the first electric appliance, is obtained by the battery pack;
configuration information is requested and obtained from an external computer system by means of the battery pack depending on the identification information;
the software is configured according to the configuration information; and
the first electric appliance is controlled by means of the battery pack by executing the configured software.

2. The method according to claim 1, wherein
the first electric appliance is positioned in a capturing range of a reader; and
the identification information is captured by means of the reader.

3. The method according to claim 2, wherein the identification information is obtained from an RFID transponder of the first electric appliance by means of the reader by radio-frequency identification, RFID.

4. The method according to claim 2, wherein a visually readable code of the first electric appliance is read by means of the reader and the identification information is determined based on the read visually readable code.

5. The method according to claim 1, wherein a digital code is obtained by means of the battery pack via a connection of the battery pack to the first electric appliance and the identification information is determined based on the digital code.

6. The method according to claim 1, wherein
a voltage value and/or a resistance value on at least one electrical contact of the battery pack are determined, while the battery pack is electrically connected to the first electric appliance; and
the identification information is determined based on the voltage value and/or the resistance value.

7. The method according to claim 1, wherein
a plurality of datasets is stored on the external computer system, wherein a first dataset of the plurality of datasets contains the configuration information and at least one second dataset of the plurality of datasets contains respective further configuration information for the at least one second electric appliance;
in response to the request of the configuration information, the first dataset is selected from the plurality of datasets depending on the identification information and transferred to the battery pack by means of the external computer system.

8. The method according to claim 1, wherein
a predefined first control operation for controlling the first electric appliance is requested, the request of the first control operation is captured by means of the battery pack and the first electric appliance is controlled by means of the battery pack depending on the configuration information or by the execution of the configured software for performing the first control operation; and/or
a predefined second control operation for controlling the battery pack is requested, the request of the second control operation is captured by means of the battery pack and the second control operation is performed by means of the battery pack depending on the configuration information or by the execution of the configured software.

9. The method according to claim 8, wherein a user input is recognized and the request of the first control operation and/or of the second control operation is captured depending on the user input.

10. The method according to claim 9, wherein a current project step of a project to be performed is determined depending on the user input and the first control operation and/or the second control operation are requested depending on the current project step.

11. The method according to claim 8, wherein
an operating current for operating an electrical or electronic load of the first electric appliance and/or an operating voltage for operating the load and/or a power output of an energy source to the load are monitored by means of the battery pack;
a current project step of a project to be performed is determined depending on a result of the monitoring; and
the first control operation and/or the second control operation are requested depending on the current project step.

12. The method according to claim 8, wherein
by means of the battery pack, status information is obtained by means of wireless communication and a current project step of a project to be performed is determined depending on the status information; and
the first control operation and/or the second control operation are requested depending on the current project step.

13. The method according to claim 1, wherein
a predefined third control operation for controlling a third electric appliance is requested and the request of the third control operation is captured by means of the battery pack;
depending on the configuration information or by execution of the configured software, a message is transferred from the battery pack to the third electric appliance; and
the third control operation is performed by means of the third electric appliance depending on the transferred message.

14. The method according to claim 13, wherein the third control operation is requested depending on an activation of the first electric appliance.

15. A battery pack, which is selectively connectable to a first electric appliance and at least one second electric appliance, wherein
the battery pack comprises a storage element, which stores a generic software for controlling the first electric appliance and the at least one second electric appliance;
the battery pack comprises a processing circuit, which is configured to obtain identification information, which identifies the electric appliance;
the battery pack comprises a communication interface, which is configured for wireless data exchange with an external computer system, wherein the processing circuit is configured to wirelessly request and obtain configuration information from the external computer system via the communication interface depending on the identification information;
the processing circuit is configured to configure the software according to the configuration information and to control the first electric appliance by execution of the configured software.
